(19) United States
(12) Patent Application Publication
(10) Pub. No.: US 2012/0043999 A1
(43) Pub. Date: Feb. 23, 2012

(54) MEMS STABILIZED OSCILLATOR

(76) Inventors: Emmanuel P. Quevy, El Cerrito, CA (US); Susumu Hara, Austin, TX (US); Jeffrey L. Sonntag, Austin, TX (US)

(21) Appl. No.: 13/285,608

(22) Filed: Oct. 31, 2011

Related U.S. Application Data
(63) Continuation-in-part of application No. 13/068,117, filed on May 3, 2011.
Application No. 13/068,117 is a continuation of application No. 12/217,190, filed on Jul. 1, 2008, now Pat. No. 7,982,550.

(51) Int. Cl. H03L 7/06

(52) U.S. Cl. 327/147

(57) ABSTRACT

A voltage controlled crystal oscillator (VCXO) is locked to a MEMS oscillator with a variable frequency ratio that is a function of a sensed temperature. That allows the long-term stability of the MEMS oscillator and temperature compensation to be reflected in a VCXO output signal having good short-term stability.

### CROSS-REFERENCE TO RELATED APPLICATION(S)

This application is a continuation-in-part of application Ser. No. 13/068,117 filed May 3, 2011, entitled “Highly Accurate Temperature Stable Clock Based on Differential Frequency Discrimination of Oscillators,” naming as inventors Emmanuel P. Quevy et al., which is a continuation of application 12/217,190, filed Jul. 1, 2008, now U.S. Pat. No. 7,982,550, entitled “Highly Accurate Temperature Stable Clock Based on Differential Frequency Discrimination of Oscillators,” naming as inventors Emmanuel P. Quevy et al., which applications are incorporated herein by reference in their entirety.

### BACKGROUND

1. Field of the Invention

This invention relates to oscillators and more particularly to compensation of oscillator circuits.

2. Description of the Related Art

Oscillators are used in a wide variety of electronic products to provide timing signals. However, oscillators can be affected by temperature and thus various compensation schemes have been utilized to address temperature affects. For example, existing temperature compensated crystal oscillator (TCXO) modules (used e.g., in global positioning systems (GPS) or wireless transceivers) include a quartz resonator and an integrated circuit chip (CMOS or otherwise) in a ceramic vacuum package. A crystal oscillator is an oscillator that includes a resonator and an electronic circuit to sustain the oscillation. A crystal oscillator exploits the mechanical resonance of a vibrating piezoelectric material (quartz crystal) used as the resonator. The TCXO includes oscillator driving circuitry and a temperature sensor with an open loop compensation circuit (function generator) that corrects frequency drift as a function of the temperature sensor response. Calibration of the TCXO to generate data for the compensation function is typically done by multiple insertions (e.g., >5) of the finished part at various temperatures to extract the temperature characteristic of the oscillator.

Another existing compensation scheme is associated with a digitally compensated crystal oscillator (DCXO). The DCXO is similar to the TCXO except the circuitry is part of a bigger transceiver SoC. The quartz resonator is off chip and the oscillator cannot be calibrated with the quartz. To address calibration, DCXOs do not include temperature sensors, but rely instead on the measurement of the frequency control burst (FCB) generated by a GSM base transceiver station (BTS) as a mechanism to compensate for absolute error. The BTS transmits a FCB on the frequency control channel (FCCH). The handset receives the FCB, calculates the frequency error, and adjusts the frequency accordingly. The frequency adjustment is comprehensive and thus eliminates the need for special sensors, provided that the DCXO can compensate for the full range of errors.

In still another approach to overcoming temperature affects, oven controlled crystal oscillators try to maintain a stable temperature for the crystal oscillator.

While the various approaches to temperature compensation described above can be effective, improvements in temperature compensation techniques are desirable.

### SUMMARY

Accordingly, in one embodiment an apparatus includes a Micro Electrical Mechanical System (MEMS) oscillator and a voltage controlled crystal oscillator (VCXO) configured to supply an output signal that is locked to an output signal of the MEMS oscillator. Locking circuitry maintains a desired frequency ratio between the output signal of the VCXO and the output signal of the MEMS oscillator. The desired frequency ratio is determined at least in part, according to temperature.

In another embodiment a method is provided that includes locking a voltage controlled crystal oscillator (VCXO) to a MEMS oscillator. The method further includes maintaining a desired frequency ratio between a VCXO output signal and a MEMS output signal and adjusting the desired frequency ratio according to a sensed temperature.

In another embodiment a method is provided that includes locking a crystal oscillator to a MEMS oscillator with a variable frequency ratio that is a function of a sensed temperature.

### BRIEF DESCRIPTION OF THE DRAWINGS

The present invention may be better understood, and its numerous objects, features, and advantages made apparent to those skilled in the art by referencing the accompanying drawings.

FIG. 1 illustrates an embodiment of the invention in which a VCXO is locked to a MEMS oscillator and the MEMS oscillator is temperature compensated.

FIG. 2 illustrates another embodiment in which a VCXO is locked to a MEMS oscillator and a frequency ratio of the MEMS oscillator and VCXO.

FIG. 3A illustrates an exemplary embodiment of locking circuitry utilizing a fractional-N phase-locked loop (PLL).

FIG. 3B illustrates an exemplary embodiment of locking circuitry utilizing a frequency-locked loop (FLL).

FIG. 4 illustrates another exemplary embodiment of locking circuitry utilizing frequency counters.

FIG. 5 illustrates a temperature versus frequency curve for an exemplary MEMS oscillator.

FIG. 6 illustrates an exemplary embodiment of a VCXO locked to a MEMS oscillator.

FIG. 7 illustrates frequency versus temperature curves for an exemplary MEMS oscillator and crystal oscillator.

FIG. 8 illustrates another exemplary embodiment of a VCXO locked to a MEMS oscillator.

FIG. 9 illustrates another exemplary embodiment of a crystal oscillator locked to a MEMS oscillator.

The use of the same reference symbols in different drawings indicates similar or identical items.

### DESCRIPTION OF THE PREFERRED EMBODIMENT(S)

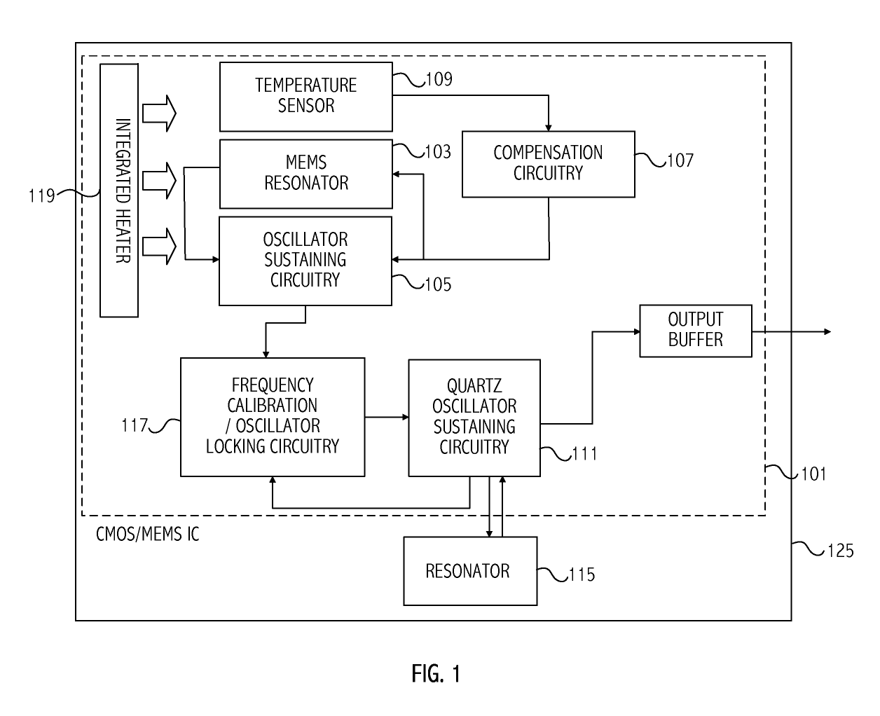

Referring to FIG. 1, according to an embodiment, a temperature compensated oscillator is formed using two oscillators. The first oscillator is a Micro Electrical Mechanical System (MEMS) oscillator and the second oscillator is an oscillator with a frequency controllable high Q resonator (e.g., a voltage controlled crystal oscillator (VCXO)). MEMS generally refers to an apparatus incorporating a mechanical structure capable of movement. MEMS are commonly used as resonators in timing applications, in accelerometers, and in inertial sensors. Certain structural components of a MEMS device are typically capable of some form of mechanical motion. The MEMS device can be formed using fabrication techniques similar to techniques used in the electronics industry such as Low Pressure Chemical Vapor Deposition, (LPCVD), Plasma Enhanced CVD (PECVD), patterning using photolithography, and Reactive Ion Etching (RIE), etc.

In the embodiment of FIG. 1, the MEMS oscillator provides an accurate reference frequency with low power and low-cost temperature compensation. The VCXO provides low jitter with low power. A single integrated circuit die 101 combines the MEMS resonator 103 and the control circuit (oscillator sustaining circuit) 105 to form an oscillator with the MEMS resonator. Use of a MEMS-based oscillator allows two important features of MEMS oscillators to be exploited. First, fabrication of MEMS oscillators is compatible with CMOS manufacturing processes and can be integrated on the same substrate with other circuits, thus providing a low cost of manufacturing and a small footprint. In addition, MEMS oscillators have good long-term stability. One shortcoming of MEMS oscillators is that they tend to have short-term stability issues that are reflected in phase noise or jitter. In addition, certain MEMS oscillators can be affected by variations in temperature.

In order to address variations in temperature in an embodiment, compensation circuitry 107 compensates the MEMS oscillator for temperature changes. A temperature sensor 109 senses a temperature and provides an indication of the sensed temperature to the compensation circuitry. The temperature sensor can be implemented using a variety of approaches. For example, multiple MEMS resonators can be used that are built with materials having different temperature coefficients and thus resonate at a frequency that correlates to temperature. Alternatively, the temperature characteristics of semiconductor devices, such as a diode, can be exploited to sense temperature. Or, the temperature characteristics of passive components, such as resistors or capacitors, can be exploited to provide a suitable temperature sensor. Once the temperature is sensed, the temperature is provided to the compensation circuitry to generate a signal to alter the oscillator sustaining circuitry. The compensation circuitry may include non-volatile memory (e.g., one-time programmable (OTP) memory), to store values corresponding to the temperature that is used to adjust the oscillator. The temperature compensation may be implemented as an equation representing a temperature curve, and one or more variables associated with a particular temperature may be stored in the memory and applied to compensate for temperature, or some other temperature compensation technique may be utilized. In other embodiments a MEMS oscillator may be utilized that is relatively immune to temperature changes by, e.g., forming the MEMS device of materials with different temperature coefficients to reduce sensitivity to temperature changes. System requirements and the sensitivity of the MEMS resonator to temperature change dictate whether temperature compensation is required in a particular embodiment.

In an embodiment of FIG. 1, the MEMS oscillator provides an output signal that is temperature compensated. In order to address the short-term stability issues with MEMS oscillators described above, an oscillator with good short-term stability can be combined with the MEMS oscillator in the various embodiments described herein to overcome the shortcomings associated with MEMS oscillators.

Thus, still referring to FIG. 1, in the embodiment illustrated, the second oscillator includes an oscillator sustaining circuit 111 to form a voltage controlled crystal oscillator (VCXO) with an external quartz resonator 115. The oscillator sustaining circuit typically includes an amplifier to amplify the oscillating voltage provided by the resonator and feed back an appropriate signal to sustain the oscillation. Quartz-based crystal oscillators provide good short-term stability and thus good phase noise and jitter performance. With respect to the crystal oscillator, quartz-based crystal oscillators typically do not have as good long-term stability as the MEMS oscillator. In addition, the output of the crystal oscillator can vary with temperature and other environmental factors such as movement and stress.

Accordingly, rather than compensate the crystal oscillator with a temperature compensation scheme that senses temperature at a location that is typically relatively distant from the resonator, instead, the crystal oscillator is locked to the MEMS oscillator. That allows the long-term stability of the MEMS oscillator to be reflected in the output of the crystal oscillator. In addition, because the MEMS oscillator is temperature compensated (or not temperature sensitive), by locking the crystal oscillator to the MEMS oscillator, a temperature compensated signal is also provided by the crystal oscillator. Thus, both long-term stability and temperature compensation is present in the output of the crystal oscillator by stabilizing the crystal oscillator output with the MEMS oscillator output.

In order to lock the crystal oscillator to the MEMS oscillator, locking circuitry 117 adjusts the output of the crystal oscillator to maintain a desired frequency ratio between the MEMS oscillator and the VCXO. The desired frequency ratio may be programmable to allow, e.g., for trimming.

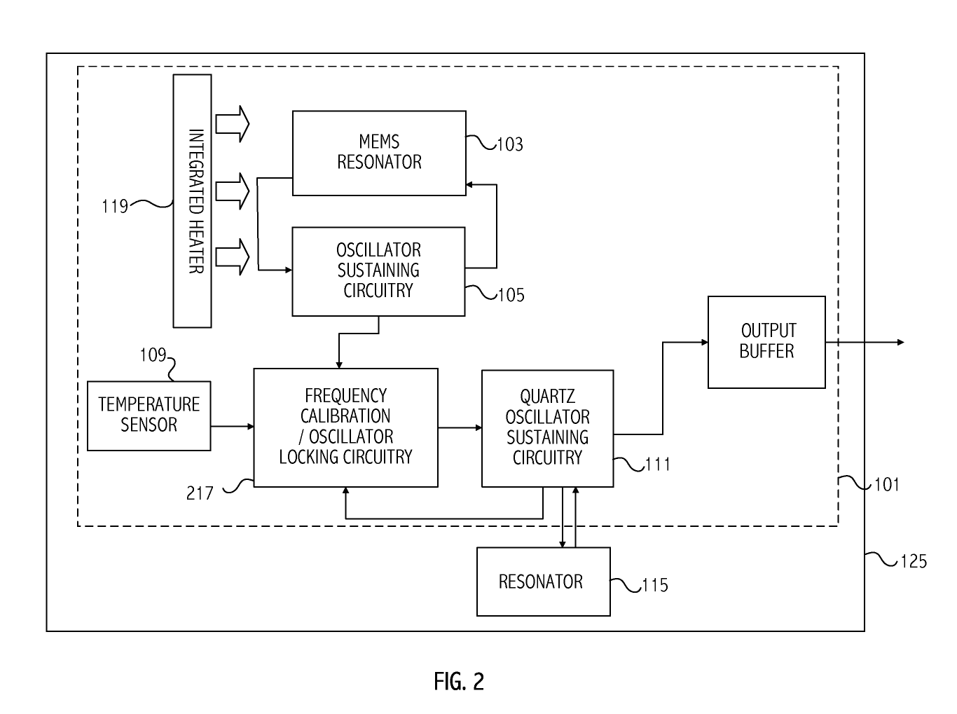

In the embodiments shown in FIG. 1, the MEMS oscillator is temperature compensated and a locking ratio is utilized to ensure that the VCXO clock and the MEMS clock stay locked. Referring to FIG. 2, in another embodiment, the temperature sensor is provided to frequency calibration/locking security 217 so that the locking ratio (the desired ratio between the MEMS frequency and the quartz frequency) may be adjusted rather than temperature compensating the MEMS oscillator. That can be significantly simpler and more effective than trying to temperature compensate the crystal oscillator. The temperature sensor 109 shown in FIGS. 1 and 2, while shown as separate for ease of illustration, may be formed as part of the MEMS resonator. Alternatively, the temperature sensor 109 may be formed on the same structural layer of the integrated circuit die as the MEMS resonator. The temperature sensor may be, e.g., a temperature dependent resistor. Locating the temperature sensor and the heater in close proximity to, or as part of the MEMS device, can increase the accuracy of the calibration and compensation approaches described herein.

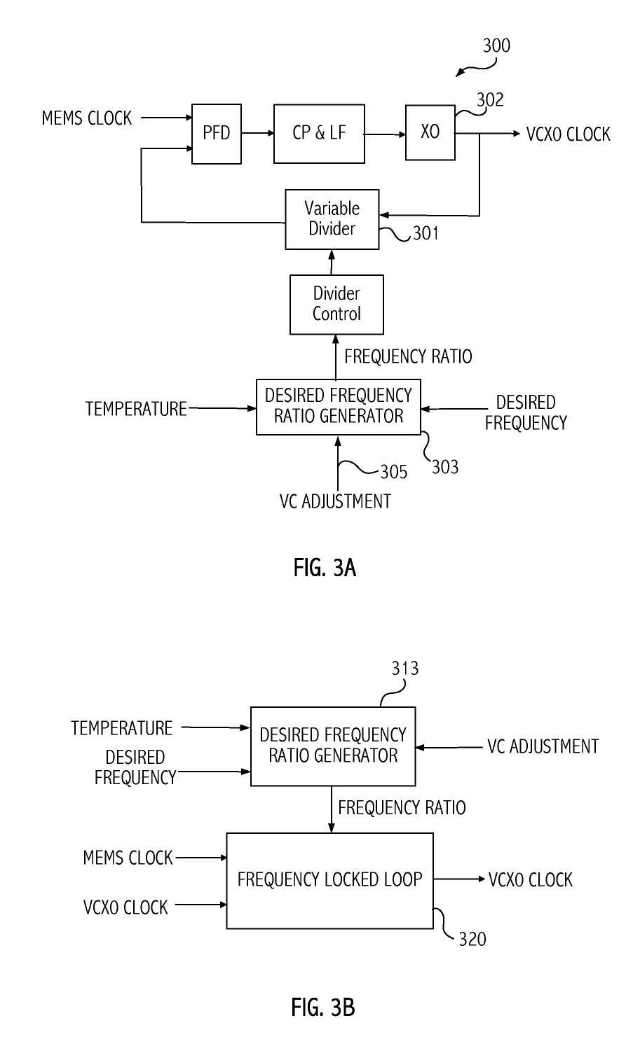

Referring to FIG. 3A, an exemplary implementation of the frequency calibration/locking circuitry 217 in FIG. 2 is shown, along with crystal oscillator (XO) 302, which shown in FIG. 2 as quartz resonator 115 and quartz resonator sustaining circuitry 111. The locking circuitry may be implemented as a fractional-N phase-locked loop (PLL) 300. The divider value for variable divider 301 is based on the desired frequency ratio. A desired frequency ratio generator block 303 determines the desired frequency ratio based on several factors. The first factor is the desired frequency of the VCXO. The desired frequency may be, e.g., R times the frequency of the MEMS oscillator, where R is a real number. Typically, the VCXO is a non-integer multiple of the MEMS oscillator, but it is possible in some circumstances for there to be an integer relationship. Thus, the value of R determines, in part, the desired frequency ratio. Typically, in a fractional-N loop the divider control utilizes a delta sigma modulator to provide the divider value based on the desired frequency ratio.

A second factor that determines the desired frequency ratio, and thus the divider control value, is the temperature. The sensed temperature will be used to further adjust the frequency ratio. The temperature may be used as an index to a look-up table to determine the correct temperature adjustment. An equation may be utilized, e.g., a fifth order compensation curve, for frequency compensation versus temperature to adjust the frequency ratio based on the temperature. The calculation or lookup logic can determine the appropriate scale factor by accessing a memory (not shown). The desired frequency ratio generator may be implemented, in a programmed microcontroller, in hardware or in combination.

In some embodiments, the frequency of the VCXO may be further adjusted using an external control signal. For example, in an embodiment, a voltage control signal VC is supplied on an external pin. That voltage may be converted to a digital signal, have an appropriate gain factor applied and supplied as VC adjustment 305 to further adjust the frequency ratio.

Referring to FIG. 3B, in another embodiment, a frequency-locked loop 320 is used to maintain the desired frequency ratio between the XO clock and the MEMS clock. The desired frequency ratio generator block 313 is similar in functionality to the desired frequency ratio block 303.

While FIGS. 3A and 3B show a PLL and an FLL to maintain the desired ratio, a particular embodiment may use any control loop that is appropriate to maintain the desired frequency ratio between the XO and the MEMS oscillator. The particular control loop chosen may be based on system requirements, available power, and available system resources such as processing power and available space.

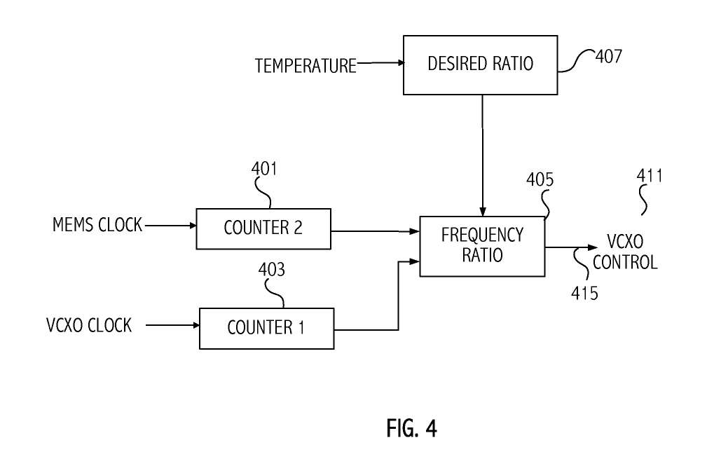

Referring to FIG. 4, an exemplary implementation of the frequency calibration/locking circuitry 217 in FIG. 2 is shown. Frequency counters 401 and 403 count the MEMS clock and the VCXO clock, respectively. The frequency ratio logic 405 determines the ratio between the two counters by periodically evaluating their contents, e.g., when one of the counters reaches its maximum or minimum value and compares the determined ratio to the desired ratio to generate VCXO control 415. In the embodiment of FIG. 4, the desired ratio logic 407 determines the desired ratio based on the desired XO frequency and the sensed temperature. The ratio logic 405 and the desired ratio logic 407 ensure the desired XO frequency is maintained by varying the frequency ratio between the MEMS oscillator and the XO as a function of a sensed temperature. The ratio logic and desired ratio logic may be implemented in dedicated hardware, a programmed processor such as a microcontroller, or some appropriate combination of both.

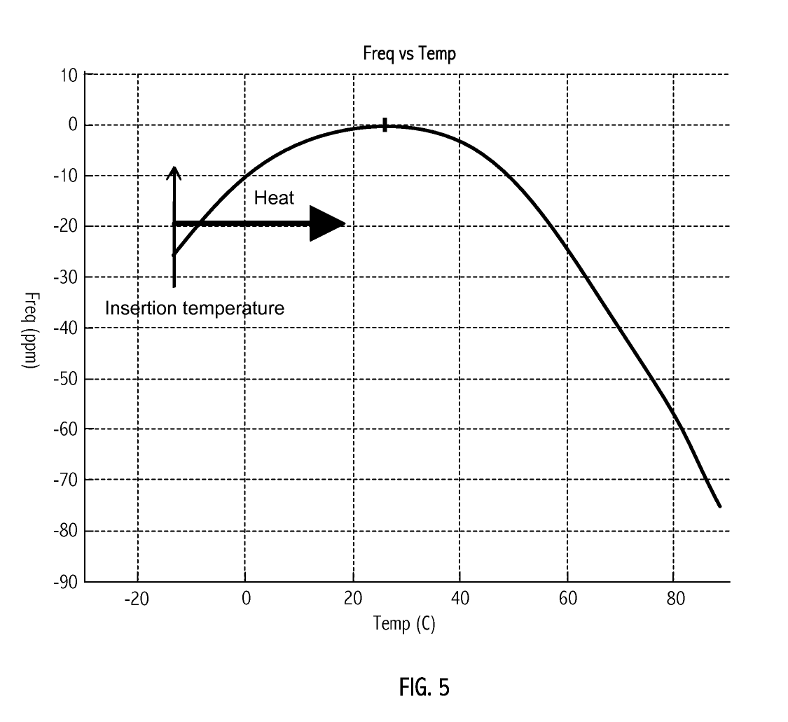

Referring to FIG. 5, illustrated is a graph of frequency versus temperature for an exemplary MEMS oscillator device without frequency compensation. Note that the frequency is given in parts per million (PPM). As can be seen, the frequency is relatively flat over only a narrow range of temperature. Thus, temperature compensation is required to reduce the PPM variations of the exemplary MEMS oscillator over temperature. One advantage of the approach herein is that by temperature compensating the MEMS oscillator, or by adjusting the frequency ratio between the XO and the MEMS oscillator, an on-board heater 119 (see FIG. 1 or 2) can be used to heat the MEMS oscillator during calibration. In contrast, the calibration process across temperature for a typical prior art TCXO device moved the part through multiple ovens, measuring the frequency drift at each temperature, with multiple insertions (>5) to determine an appropriate compensation curve. That information was then stored in the TCXO. While shown separately in FIGS. 1 and 2 for ease of illustration, the heater 119, in an embodiment, can be formed as part of the MEM resonator itself rather than part of the die substrate. Other embodiments may place the heater in a location appropriate for both fabrication and heating purposes according to such factors as process technology and calibration needs.

With the device of FIG. 1 or 2, in order to calibrate for temperature, the device can be tested at a single external temperature without an oven or ovens. Instead, the heater 119 heats the MEMS oscillator to temperatures to obtain temperature characterization data, such as that shown in FIG. 5, over the appropriate temperature range. The on-board temperature sensor can be used to measure the temperature of the MEMS oscillator. Thus, the temperature characteristics of the MEMS oscillator can be extracted without the need for ovens. The MEMS oscillator frequencies are compared at multiple temperatures to the target frequency. An equation is obtained, e.g., a fifth order compensation curve, for frequency compensation versus temperature for the MEMS oscillator or to compensate the frequency ratio. During operation, the MEMS oscillator is operated with temperature compensation, or instead, the frequency ratio between the MEMS oscillator and the VCXO is adjusted to calibrate for temperature change, using the frequency compensation curve obtained from the factory calibration.

The calibration achieved using an integrated heater that is on chip close to, or as part of the element that needs to be characterized and compensated, is faster and cheaper. Thus, lower-cost manufacturing can be achieved as compared to, e.g., a TCXO requiring ovens and multiple insertions to obtain suitable compensation data, due to faster testing and calibration cycles for both wafer level and/or package level. Further, removing the need for ovens reduces cost of the testing facilities.

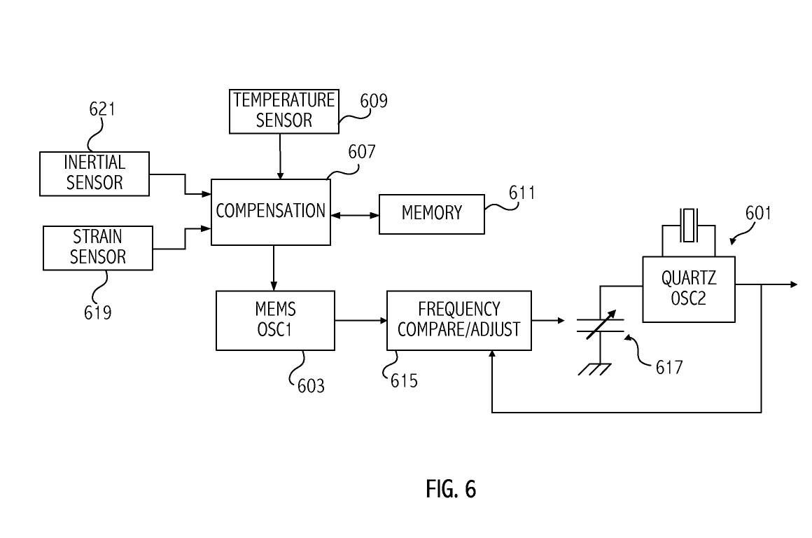

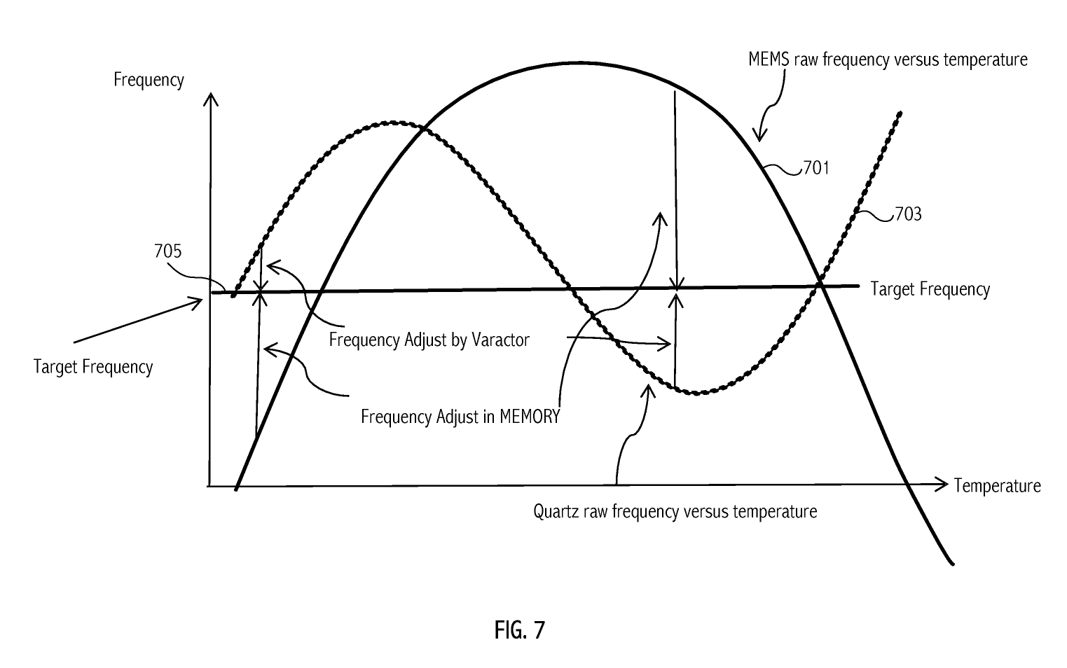

Referring to FIG. 6, illustrated is a block diagram of an embodiment of the invention illustrating how a quartz oscillator 601 can be configured to follow the MEMS oscillator 603. FIG. 7 illustrates an exemplary graph of how temperature affects both the MEMS frequency 701 and the quartz frequency 703. Referring to FIGS. 6 and 7, the MEMS frequency 701 is adjusted based on the temperature characterization that was performed to extract compensation data during factory calibration, such as the data associated with the curve shown in FIG. 5. Assuming the target frequency 705 shown in FIG. 7, a frequency compensation curve is applied to the MEMS oscillator using compensation block 607 based on the temperature characterization of the MEMS oscillator and the temperature sensed by temperature sensor 609. Referring to FIG. 7, the adjustment from the memory based on the temperature is used to drive the MEMS raw frequency 701 towards the target frequency 705. The compensation curve parameters may be stored in the memory 611. Based on the comparison in compare/adjust block 615, the frequency of the quartz oscillator is adjusted through, e.g., adjusting varactor 617. That adjustment drives the crystal oscillator frequency 603 towards its target frequency, which is a multiple, integer or fractional, of the MEMS frequency. Note that while the target frequency for the MEMS and VCXO is shown as the same in FIG. 7 for ease of illustration, in fact, the frequencies are almost always different.

While temperature may have a significant effect on the MEMS oscillator output, other environmental factors such as strain or vibration may also cause frequency drift. Accordingly, embodiments may include a strain sensor 619 and/or an inertial sensor 621 and compensate the frequency based on sensed environmental effects. Other actuators in addition to a heater, such as an inertial table, can be integrated on chip to provide an environmental stimulus against which the device is calibrated for environmental factors other than temperature. Note that better sensing accuracy is achieved by minimizing the distance from the environmental sensor (e.g., temperature, strain, inertial) to the device to be sensed (e.g., oscillator and/or resonator).

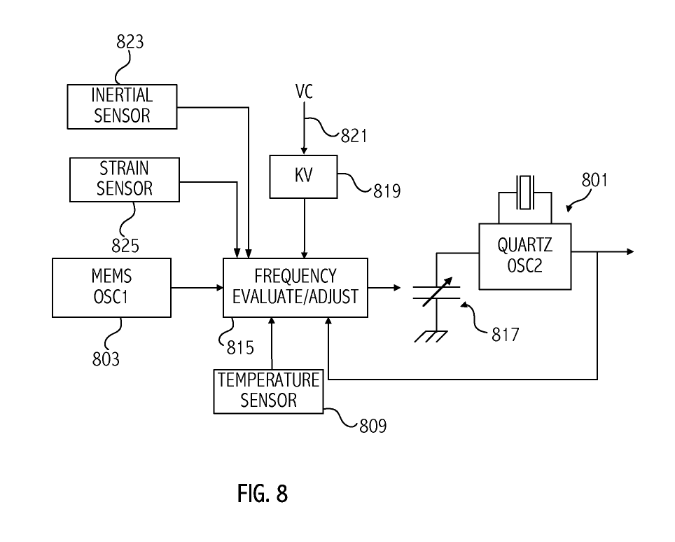

Alternatively, the frequency ratio of the VCXO and MEMS is adjusted to adjust the frequency of the VCXO as shown in FIG. 8. Frequency compare/adjust block 815 receives temperature information, and provides a control signal for varactor 817. The compare/adjust block 815 may operate in a manner similar to the control loop embodiments shown in FIGS. 3A, 3B, or 4. Note that in addition to the temperature sensor 809, an inertial sensor 823 or a strain sensor 825 may also be used to adjust the frequency ratio.

In an embodiment, an external voltage control signal 821 is utilized to control the frequency of the VCXO. The external voltage control signal is converted to a digital signal in an analog to digital converter and a gain (KV) is applied to the value and supplied to frequency adjust block 815 to adjust the frequency ratio. Of course, the external control 821 may be supplied as a digital signal, e.g., over a serial interface rather than as an analog signal. Further, a serial interface (I/F) may be used to adjust any of the values described herein, such as the desired frequency, or loop parameters of the control loops shown in FIGS. 3 and 4.

While the discussion above has focused on quartz crystal oscillators, the oscillator that gets “MEMS-stabilized” is not limited to simple quartz. In fact, multiple resonators, such as a 3rd overtone resonator, a mesa-resonator, a surface acoustic wave (SAW) device, or a film bulk acoustic resonator (FBAR), can also be used as the MEMS-stabilized oscillator. With a SAW oscillator, very high frequency and good noise performance can be achieved and fully benefit from the stability of the MEMS oscillator.

Referring again to FIG. 1, integrated circuit die 101 may be packaged with resonator 115 in a single package 125. In other embodiments, the die and the quartz may be packaged separately. Embodiments of the invention may allow for less expensive packaging materials. For example, there is no need to use a package where the crystal is separated to avoid contamination. In addition, a lower cost crystal may be utilized. Aging issues associated with crystal oscillators may be less important because of the long-term stability of the MEMS oscillator.

Thus, according to embodiments of the invention, a MEMS-based oscillator is used for its best feature, i.e. compatibility with CMOS and low cost of manufacturing, small form factor, and long-term stability. Quartz-based (or other types) oscillators are used for their best features, e.g., short-term stability.

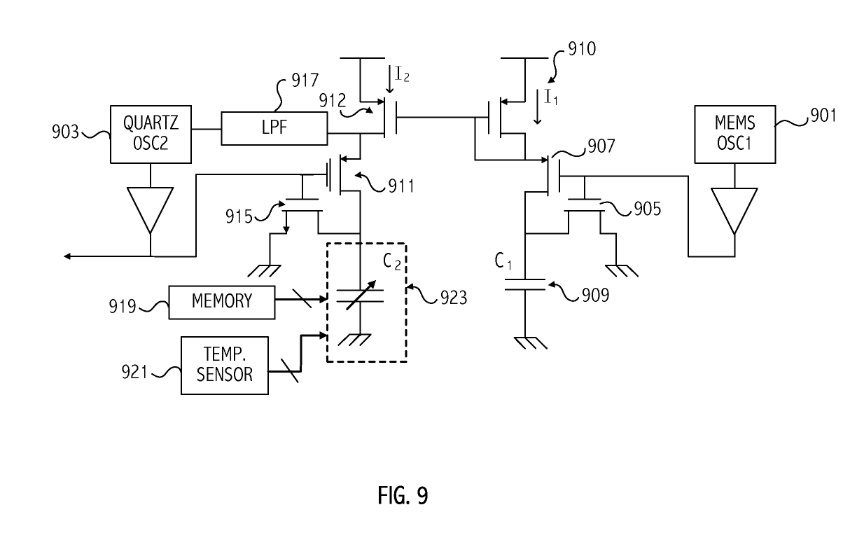

FIG. 9 illustrates another embodiment for frequency locking a quartz oscillator to a MEMS oscillator. The embodiment shown in FIG. 9 allows for frequency locking and allows for fractional frequency differences between the MEMS oscillator 901 and the quartz oscillator 903. The embodiment of FIG. 9 includes a switched capacitor circuit that includes transistors 905, 907 and capacitor C₁ 909 and creates a current I₁ that is proportional to the MEMS oscillator frequency by charging C₁ during one portion of the oscillation cycle through transistor 907 and discharging C₁ during the another portion of the oscillation cycle through transistor 905. The current I₁ is mirrored as I₂ using transistors 912 and 912. A switched capacitor circuit is formed on the quartz side with transistors 911 and 915 and capacitor C₂. The mirrored current I₂ charges and discharges the capacitor C₂ based on the oscillation of the quartz oscillator. The frequency of the quartz oscillator

$${f}_{quartz} = \frac{{C}_{1} \cdot {f}_{MEMS}}{{C}_{2}} ,$$

where f_{MEMS} is encoded in the mirrored current. Low pass filter 917 reduces the step function typically present in switched capacitor circuits. A memory 919 and temperature sensor 921 may be used to adjust varactor 923 and thus C₂ based on measured temperature, desired frequency, and other sensor or control inputs if available.

Thus, various approaches have been described that exploit the long-term stability of the MEMS oscillator with the short-term stability of the crystal oscillator. The description of the invention set forth herein is illustrative, and is not intended to limit the scope of the invention as set forth in the following claims. Other variations and modifications of the embodiments disclosed herein, may be made based on the description set forth herein, without departing from the scope of the invention as set forth in the following claims.

What is claimed is:

1. An apparatus comprising:
a Micro Electrical Mechanical System (MEMS) oscillator; and
a crystal oscillator (XO) configured to supply an output signal that is locked to an output signal of the MEMS oscillator.

2. The apparatus as recited in claim 1 further comprising:
locking circuitry to maintain a desired frequency ratio between the output signal of the XO and the output signal of the MEMs oscillator.

3. The apparatus as recited in claim 2 further comprising:
a temperature sensor,
wherein the desired frequency ratio is adjusted according to a temperature sensed by the temperature sensor.

4. The apparatus as recited in claim 3, wherein the temperature sensor is formed as part of a MEMS resonator forming the MEMS oscillator.

5. The apparatus as recited in claim 3, wherein the temperature sensor is formed on a structural layer of a die on which a MEMS resonator is formed, the MEMS resonator forming a part of the MEMS oscillator.

6. The apparatus as recited in claim 2, wherein the locking circuitry comprises a frequency-locked loop or a phase-locked loop.

7. The apparatus as recited in claim 2 wherein the desired frequency ratio is determined, at least in part, according to a desired frequency of the XO.

8. The apparatus as recited in claim 2 further comprising:
an inertial sensor,
wherein the desired frequency ratio is adjusted according to an output of the inertial sensor.

9. The apparatus as recited in claim 2 further comprising:
a strain sensor,
wherein the desired frequency ratio is adjusted according to an output of the strain sensor.

10. The apparatus as recited in claim 1 wherein the MEMS oscillator includes a MEMS resonator and a MEMS oscillator sustaining circuit.

11. The apparatus as recited in claim 1 wherein the XO output frequency is determined according to a control signal determined, at least in part, based on an output of the MEMS oscillator.

12. The apparatus as recited in claim 1,
wherein the crystal oscillator includes a crystal resonator and a crystal oscillator sustaining circuit; and
wherein the MEMS oscillator and the crystal oscillator sustaining circuit are disposed on an integrated circuit die.

13. The apparatus as recited in claim 1 further comprising a package housing the MEMS oscillator and the crystal oscillator.

14. The apparatus as recited in claim 1 further comprising:
a temperature sensor to provide a temperature indication; and
a temperature compensation circuit for the MEMS oscillator responsive to adjust a frequency of the output of the MEMS oscillator based on the temperature indication.

15. The apparatus as recited in claim 1 further comprising a heater integrated on a die with the MEMS oscillator.

16. The apparatus as recited in claim 15 the heater is formed integral with a portion of the MEMS oscillator.

17. A method comprising:
locking a crystal oscillator (XO) to a MEMS oscillator to maintain a desired frequency ratio between the XO and the MEMS oscillator; and
adjusting the frequency ratio according to a sensed temperature.

18. The method as recited in claim 17 further comprising:
using one of a frequency locked loop and a phase-locked loop to lock the XO to the MEMS oscillator.

19. The method as recited in claim 17 further comprising:
determining a frequency ratio between a XO output signal and a MEMS output signal according to a desired frequency of the XO output signal.

20. The method as recited in claim 19, further comprising:
receiving a control signal indicating a change to the desired frequency of the XO output signal; and
adjusting the desired frequency ratio according to the change.

21. The method as recited in claim 19 wherein the control signal is an analog voltage signal.

22. A method comprising:
locking a crystal oscillator to a MEMS oscillator with a variable frequency ratio that is a function of a sensed temperature.

23. The method as recited in claim 22 wherein the variable frequency ratio is further a function of at least one of sensed strain and sensed motion.

24. The MEM oscillator as recited in claim 22, wherein the variable frequency ratio is further a function of a control input to adjust a frequency of the crystal oscillator.
